(19) United States
(12) Patent Application Publication
(10) Pub. No.: US 2023/0363159 A1
(43) Pub. Date: Nov. 9, 2023

(54) SEMICONDUCTOR DEVICE, MEMORY DEVICE AND METHOD OF FABRICATING THE SAME

(71) Applicant: MACRONIX International Co., Ltd., Hsinchu (TW)

(72) Inventor: Pi-Shan Tseng, Hsing-Chu (TW)

(73) Assignee: MACRONIX International Co., Ltd., Hsinchu (TW)

(21) Appl. No.: 17/737,756

(22) Filed: May 5, 2022

(51) Int. Cl. H01L 27/11582

(52) U.S. Cl. CPC H01L 27/11582

(57) ABSTRACT

A memory device may be applicated in a 3D AND flash memory device. The memory device includes a gate stack structure, a doped channel stack structure, a source pillar and a drain pillar, and a plurality of dielectric structures. The gate stack structure is located on a substrate. The gate stack structure includes a plurality of gate layers and a plurality of insulating layers stacked alternately with each other. The doped channel stack structure extends through the gate stack structure. The doped channel stack structure includes a plurality of doped channel rings spaced apart from each other. The source pillar and the drain pillar extend through the doped channel stack structure. The source pillar and the drain pillar are respectively electrically connected to the plurality of doped channel rings. The plurality of dielectric structures are located between the plurality of gate layers and the plurality of doped channel rings.

### BACKGROUND

### Technical Field

The embodiment of the disclosure relates to a semiconductor device and a method of fabricating the same, and particularly to a memory device and a method of fabricating the same.

### Description of Related Art

Since a non-volatile memory has the advantage that stored data does not disappear at power-off, it becomes a widely used memory for a personal computer or other electronics equipment. Currently, the 3D memory commonly used in the industry includes a NOR memory and a NAND memory. In addition, another 3D memory is an AND memory, which may be applied to a multi-dimensional memory array with high integration and high area utilization, and has an advantage of a fast operation speed. Therefore, the development of a 3D AND flash memory device has gradually become the current trend.

### SUMMARY

The embodiment of disclosure provides a memory device to have a plurality of channel rings which are spaced apart from each other and are doped to reduce leakage current, increase the device window, improve the turn-on current.

The embodiment of disclosure provides a method of fabricating a memory device which may be integrated with the existing process.

A memory device according to an embodiment of the disclosure includes a gate stack structure, a doped channel stack structure, a source pillar and a drain pillar, and a plurality of dielectric structures. The gate stack structure is located on a substrate. The gate stack structure includes a plurality of gate layers and a plurality of insulating layers stacked alternately with each other. The doped channel stack structure extends through the gate stack structure. The doped channel stack structure includes a plurality of doped channel rings spaced apart from each other. The source pillar and the drain pillar extend through the doped channel stack structure. The source pillar and the drain pillar are respectively electrically connected to the plurality of doped channel rings. The plurality of dielectric structures are located between the plurality of gate layers and the plurality of doped channel rings.

A method of fabricating a memory device according to an embodiment of the disclosure includes the following steps. An intermediate stack structure is formed on a substrate. The intermediate stack structure includes a plurality of first interlayers and a plurality of second interlayers stacked alternately with each other. An opening is formed in the intermediate stack structure. A channel pillar is formed on sidewalls of the opening. A source pillar and a drain pillar are formed within the channel pillar. The source pillar and the drain pillar are electrically connected to the channel pillar. The plurality of first interlayers are removed to form a plurality of first horizontal openings. The part of the channel pillar exposed by the plurality of first horizontal openings are removed to form a plurality of ring spaces, and the channel pillar is etched to form a plurality of channel rings. The plurality of channel rings are separated from each other by the plurality of ring spaces. The plurality of insulating layers are filled into the plurality of first horizontal openings and the plurality of ring spaces. The plurality of second interlayers are removed to form a plurality of second horizontal openings. A doping process is performed on the plurality of channel rings to form a plurality of doped channel rings. The plurality of doped channel rings and the plurality of insulating layers filled in the plurality of ring spaces are alternately stacked to form a doped channel stack structure. A plurality of gate layers are filled in the plurality of second horizontal openings. The plurality of gate layers and the plurality of insulating layers filled in the plurality of first horizontal openings alternate with each other to form a gate stack structure. A plurality of dielectric structures are formed a between the plurality of gate layers and the plurality of doped channel rings.

A semiconductor device according to an embodiment of the disclosure includes a stack structure, a vertical pillar, and two electrode pillars. The stack structure is located on the substrate, wherein the stack structure comprises a plurality of conductive layers. The vertical pillar extends through the stack structure, wherein the vertical pillar includes a plurality of channel rings spaced apart from each other, the plurality of channel rings having a first doping concentration. The two electrode pillars extend through the stack structure. The two electrode pillars are respectively electrically connected to the plurality of channel rings and have a second doping concentration. The first doping concentration is smaller than the second doping concentration.

In the embodiments of the disclosure, the channel rings are physically separated from each other with the insulating layers. This helps the gate layer to control the channel region, so as to reduce the leakage current between the memory cells, increase the device window, and improve the current ratio of turn-on and turn-off (Ion/Ioff). Furthermore, since the channel rings are doped, the threshold voltage of the device may be modulated by changing the dopant concentration of the channel region. Further, the manufacturing method of the memory device of the embodiment of the disclosure may be integrated with the existing process, in which the channel pillar penetrating through the gate stack structure is cut into a plurality of channel rings and is doped.

### BRIEF DESCRIPTION OF THE DRAWINGS

FIG. 1A shows a circuit diagram of a 3D AND flash memory array according to some embodiments in according to the present disclosure.

FIG. 1B shows a partial simplified perspective view of the memory array in FIG. 1A.

FIG. 1C and FIG. 1D show cross-sectional views taken along line I-I′ of FIG. 1B.

FIG. 1E shows a top view of line II-II′ of FIG. 1C and FIG. 1D.

FIG. 2A to FIG. 2M show cross-sectional views of a manufacturing process of a semiconductor device in according to an embodiment of the present disclosure.

### DESCRIPTION OF THE EMBODIMENTS

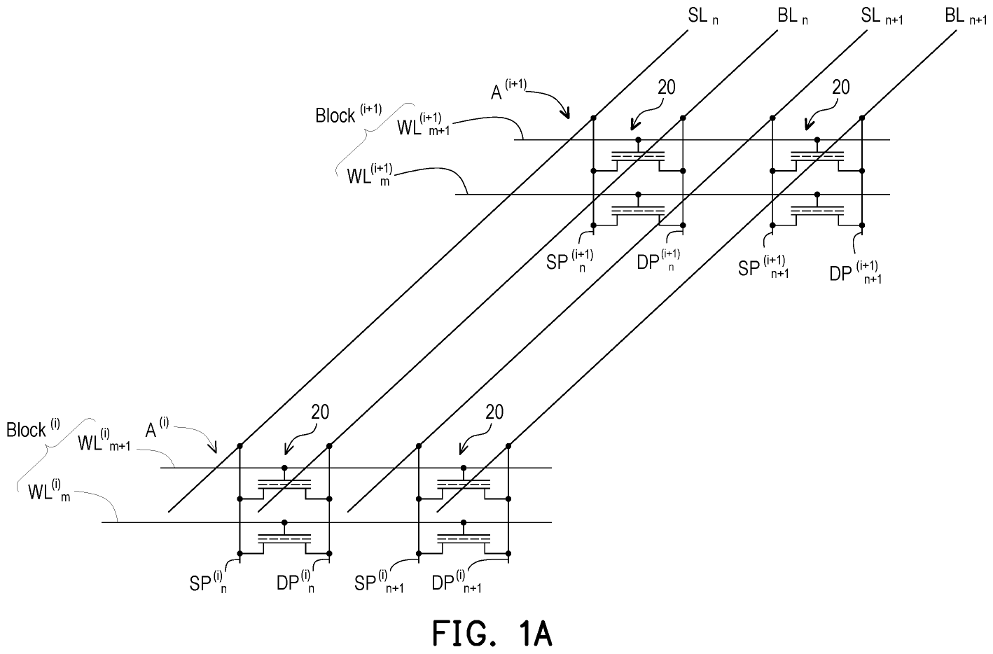

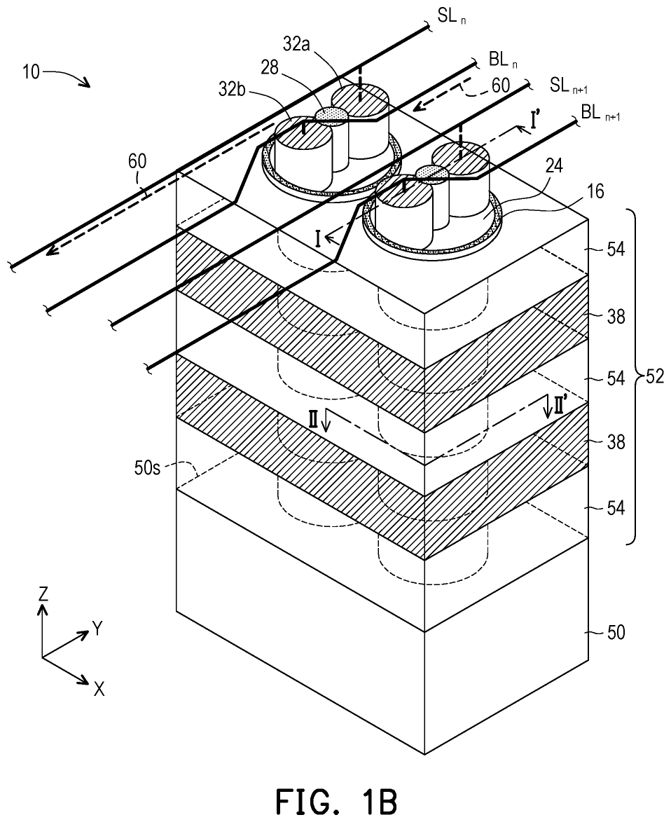

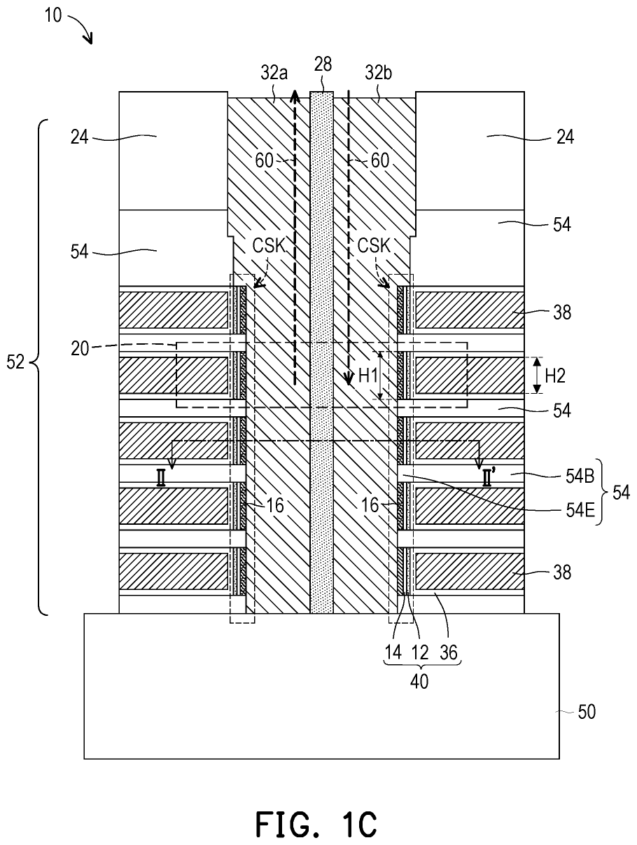

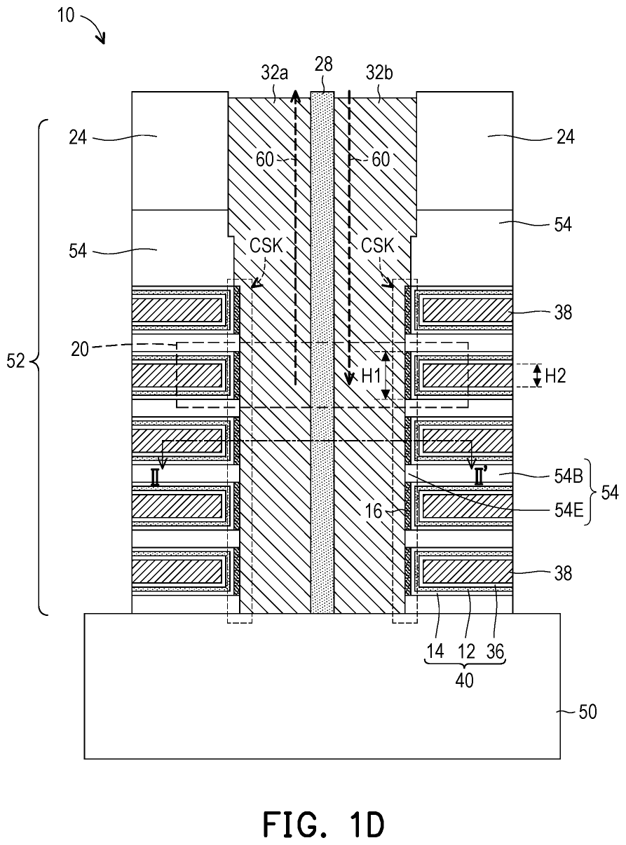

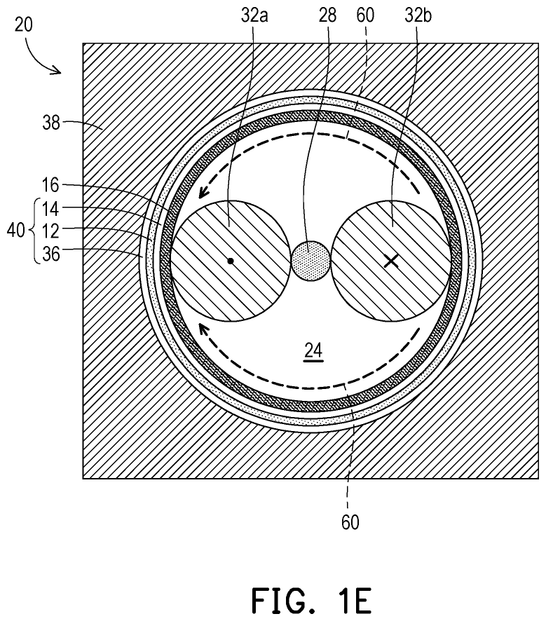

FIG. 1A shows a circuit diagram of a 3D AND flash memory array according to some embodiments in according to the present disclosure. FIG. 1B shows a partial simplified perspective view of the memory array in FIG. 1A. FIG. 1C and FIG. 1D show cross-sectional views taken along line I-I′ of FIG. 1B. FIG. 1E shows a top view of line II-II′ of FIG. 1C and FIG. 1D.

FIG. 1A shows a schematic view of two blocks BLOCK⁽ⁱ⁾ and BLOCK⁽ⁱ⁺¹⁾ of a vertical AND memory array 10 arranged in rows and columns. The block BLOCK⁽ⁱ⁾ includes a memory array A⁽ⁱ⁾. A row (e.g., an (m+1)^{th} row) of the memory array A⁽ⁱ⁾ is a set of AND memory cells 20 having a common word line (e.g., WL⁽ⁱ⁾ₘ₊₁). The AND memory cells 20 of the memory array A⁽ⁱ⁾ in each row (e.g., the (m+1)^{th} row) correspond to a common word line (e.g., WL⁽ⁱ⁾ₘ₊₁) and are coupled to different source pillars (e.g., SP⁽ⁱ⁾ₙ and SP⁽ⁱ⁾ₙ₊₁) and drain pillars (e.g., DP⁽ⁱ⁾ₙ and DP⁽ⁱ⁾ₙ₊₁), so that the AND memory cells 20 are logically arranged in a row along the common word line (e.g., WL⁽ⁱ⁾ₘ₊₁).

A column (e.g., an n^{th} column) of the memory array A⁽ⁱ⁾ is a set of AND memory cells 20 having a common source pillar (e.g., SP⁽ⁱ⁾ₙ) and a common drain pillar (e.g., DP⁽ⁱ⁾ₙ). The AND memory cells 20 of the memory array A⁽ⁱ⁾ in each column (e.g., the n^{th} column) correspond to different word lines (e.g., WL⁽ⁱ⁾ₘ₊₁ and WL⁽ⁱ⁾ₘ) and are coupled to a common source pillar (e.g., SP⁽ⁱ⁾ₙ) and a common drain pillar (e.g., DP⁽ⁱ⁾ₙ). Hence, the AND memory cells 20 of the memory array A⁽ⁱ⁾ are logically arranged in a column along the common source pillar (e.g., SP⁽ⁱ⁾ₙ) and the common drain pillar (e.g., DP⁽ⁱ⁾ₙ). In the physical layout, according to the fabrication method as applied, the columns or rows may be twisted and arranged in a honeycomb pattern or other patterns for high density or other reasons.

In FIG. 1A, in the block BLOCK⁽ⁱ⁾, the AND memory cells 20 in the n^{th} column of the memory array A⁽ⁱ⁾ share a common source pillar (e.g., SP⁽ⁱ⁾ₙ) and a common drain pillar (e.g., DP⁽ⁱ⁾ₙ). The AND memory cells 20 in an (n+1)^{th} column share a common source pillar (e.g., SP⁽ⁱ⁾ₙ₊₁) and a common drain pillar (e.g., DP⁽ⁱ⁾ₙ₊₁).

The common source pillar (e.g., SP⁽ⁱ⁾ₙ) is coupled to a common source line (e.g., SLₙ) and the common drain pillar (e.g., DP⁽ⁱ⁾ₙ) is coupled to a common bit line (e.g., BLₙ). The common source pillar (e.g., SP⁽ⁱ⁾ₙ₊₁) is coupled to a common source line (e.g., SLₙ₊₁) and the common drain pillar (e.g., DP⁽ⁱ⁾ₙ₊₁) is coupled to a common bit line (e.g., BLₙ₊₁).

Likewise, the block BLOCK⁽ⁱ⁺¹⁾ includes a memory array A⁽ⁱ⁺¹⁾, which is similar to the memory array A⁽ⁱ⁾ in the block BLOCK⁽ⁱ⁾. A row (e.g., an (m+1)^{th} row) of the memory array A⁽ⁱ⁺¹⁾ is a set of AND memory cells 20 having a common word line (e.g., WL⁽ⁱ⁺¹⁾ₘ₊₁). The AND memory cells 20 of the memory array A⁽ⁱ⁺¹⁾ in each row (e.g., the (m+1)^{th} row) correspond to a common word line (e.g., WL⁽ⁱ⁺¹⁾ₘ₊₁) and are coupled to different source pillars (e.g., SP⁽ⁱ⁺¹⁾ₙ and SP⁽ⁱ⁺¹⁾ₙ₊₁) and drain pillars (e.g., DP⁽ⁱ⁺¹⁾ₙ and DP⁽ⁱ⁺¹⁾ₙ₊₁). A column (e.g., an n^{th} column) of the memory array A⁽ⁱ⁺¹⁾ is a set of AND memory cells 20 having a common source pillar (e.g., SP⁽ⁱ⁺¹⁾ₙ) and a common drain pillar (e.g., DP⁽ⁱ⁺¹⁾ₙ). The AND memory cells 20 are integrated and connected in parallel, and thus may be also referred to as a memory string. The AND memory cells 20 of the memory array A⁽ⁱ⁺¹⁾ in each column (e.g., the n^{th} column) correspond to different word lines (e.g., WL⁽ⁱ⁺¹⁾ₘ₊₁ and WL⁽ⁱ⁺¹⁾ₘ) and are coupled to a common source pillar (e.g., SP⁽ⁱ⁺¹⁾ₙ) and a common drain pillar (e.g., DP⁽ⁱ⁺¹⁾ₙ). Hence, the AND memory cells 20 of the memory array A⁽ⁱ⁺¹⁾ are logically arranged in a column along the common source pillar (e.g., SP⁽ⁱ⁺¹⁾ₙ) and the common drain pillar (e.g., DP⁽ⁱ⁺¹⁾ₙ).

The block BLOCK⁽ⁱ⁺¹⁾ and the block BLOCK⁽ⁱ⁾ share source lines (e.g., SLₙ and SLₙ₊₁) and bit lines (e.g., BLₙ and BLₙ₊₁). Therefore, the source line SLₙ and the bit line BLₙ are coupled to the n^{th} column of AND memory cells 20 in the AND memory array A⁽ⁱ⁾ of the block BLOCK⁽ⁱ⁾, and are coupled to the n^{th} column of AND memory cells 20 in the AND memory array A⁽ⁱ⁺¹⁾ of the block BLOCK⁽ⁱ⁺¹⁾. Similarly, the source line SLₙ₊₁ and the bit line BLₙ₊₁ are coupled to the (n+1)^{th} column of AND memory cells 20 in the AND memory array A⁽ⁱ⁾ of the block BLOCK⁽ⁱ⁾, and are coupled to the (n+1)^{th} column of AND memory cells 20 in the AND memory array A⁽ⁱ⁺¹⁾ of the block BLOCK⁽ⁱ⁺¹⁾.

Referring to FIG. 1B and FIG. 1D, the memory array 10 may be disposed over an interconnect structure of a semiconductor die, for example, being disposed on one or more active devices (e.g., transistors) formed on a semiconductor substrate. Therefore, the dielectric substrate 50 is, for example, a dielectric layer (e.g., a silicon oxide layer) over a conductive interconnect structure formed on a silicon substrate. The memory array 10 may include a gate stack structure 52, a plurality of channel rings 16, a plurality of first conductive pillars (also referred to as source pillars or electrode pillars) 32a, a plurality of second conductive pillars (also referred to as drain pillars or electrode pillars) 32b, and a plurality of charge storage structures 40.

Referring to FIG. 1B, the gate stack structure 52 is formed on the dielectric substrate 50 in the array region (not shown) and the staircase region (not shown). The gate stack structure 52 includes a plurality of gate layers (also referred to as word lines) 38 and a plurality of insulating layer 54 vertically stacked on a surface 50s of the dielectric substrate 50. In a direction Z, the gate layers 38 are electrically isolated from each other by the insulating layer 54 disposed therebetween. The gate layers 38 extend in a direction parallel to the surface 50s of the dielectric substrate 50. The gate layers 38 in the staircase region may have a staircase structure (not shown). Therefore, a lower gate layer 38 is longer than an upper gate layer 38, and the end of the lower gate layer 38 extends laterally beyond the end of the upper gate layer 38. A contact (not shown) for connecting the gate layer 38 may land on the end of the gate layer 38 to connect the gate layers 38 respectively to conductive lines.

Referring to FIG. 1B to FIG. 1D, the memory array 10 further includes an insulating pillar 28, a plurality of first conductive pillars 32a, and a plurality of second conductive pillars 32b. In this example, the first conductive pillars 32a serve as source pillars. The second conductive pillars 32b serve as drain pillars. The first conductive pillar 32a, the second conductive pillar 32b and the insulating pillar 28 are each extend in a direction (i.e., the direction Z) perpendicular to the gate layer 38. The first conductive pillar 32a and the second conductive pillar 32b are separated from each other by the insulating pillar 28. The first conductive pillar 32a and the second conductive pillar 32b include doped polysilicon or metal materials. The insulating pillar 28 is, for example, silicon nitride.

Referring to FIG. 1B to FIG. 1D, the memory array 10 further includes a plurality of doped channel rings 16 stacked along the direction Z. The doped channel rings 16 is electrically connected to the first conductive pillar 32a and the second conductive pillar 32b. In some embodiments, each of the doped channel rings 16 has an annular shape from a top view. A material of the channel rings includes a doped semiconductor material, such as doped polysilicon.

Referring to FIG. 1C and FIG. 1D, the charge storage structures (also referred to as a dielectric structure) 40 is disposed on the sidewalls of the doped channel rings 16. The charge storage structures 40 are disposed between the doped channel rings 16 and the gate layers 38. Each of the charge storage structure 40 may include a tunneling layer (or referred to as a bandgap engineered tunneling oxide layer) 14, a charge storage layer 12, and a blocking layer 36. The charge storage layer 12 is located between the tunneling layer 14 and the blocking layer 36. In some embodiments, the tunneling layer 14 and the blocking layer 36 include silicon oxide. The charge storage layer 12 includes silicon nitride or other materials capable of trapping charges. In some embodiments, as shown in FIG. 1C, a portion (the tunneling layer 14 and the charge storage layer 12) of the charge storage structure 40 continuously extends in a direction (i.e., the direction Z) perpendicular to the gate layer 38, and the other portion (the blocking layer 36) of the charge storage structure 40 surrounds the gate layer 38. In other embodiments, as shown in FIG. 1D, the charge storage structure 40 (the tunneling layer 14, the charge storage layer 12, and the blocking layer 36) surrounds the gate layer 38.

Referring to FIG. 1E, the charge storage structure 40, the doped channel ring 16, the source pillar 32a, and the drain pillar 32b are surrounded by the gate layer 38, and a memory cell 20 is defined. According to different operation methods, a 1-bit operation or a 2-bit operation may be performed on the memory cell 20. For example, when a voltage is applied to the source pillar 32a and the drain pillar 32b, since the source pillar 32a and the drain pillar 32b are connected to the doped channel ring 16, electrons may be transferred along the doped channel ring 16 and stored in the entire charge storage structure 40. Accordingly, a 1-bit operation may be performed on the memory cell 20. In addition, for an operation involving Fowler-Nordheim tunneling, electrons or holes may be trapped in the charge storage structure 40 between the source pillar 32a and the drain pillar 32b. For an operation involving source side injection, channel-hot-electron injection, or band-to-band tunneling hot carrier injection, electrons or holes may be locally trapped in the charge storage structure 40 adjacent to one of the source pillar 32a and the drain pillar 32b. Accordingly, a single level cell (SLC, 1 bit) or multi-level cell (MLC, greater than or equal to 2 bits) operation may be performed on the memory cell 20.

Referring to FIG. 1A and FIG. 1B, during operation, a voltage is applied to a selected word line (gate layer) 38; for example, when a voltage higher than a corresponding threshold voltage (Vth) of the corresponding memory cell 20 is applied, the doped channel ring 16 intersecting the selected word line 38 is turned on to allow a current to enter the drain pillar 32b from the bit line BLₙ or BLₙ₊₁ (shown in FIG. 1B), flow to the source pillar 32a via the turned-on channel region (e.g., in a direction indicated by arrow 60), and finally flow to the source line SLₙ or SLₙ₊₁ (shown in FIG. 1B).

Referring to FIG. 1C and FIG. 1D, in some embodiments of the disclosure, the insulating layer 54 includes a plurality of body portions 54B and a plurality of extension portions 54E. The plurality of body portions 54B and the plurality of gate layers 38 are alternately stacked with each other to form a gate stack structure 52. The plurality of extension portions 54E are connected to the plurality of body portions 54B, and are alternately stacked with the plurality of doped channel rings 16 to form a doped channel stack structure CSK. The doped channel stack structure CSK extends through the gate stack structure 52.

Referring to FIG. 1C and FIG. 1D, from a cross-sectional view, the doped channel rings 16 of the doped channel stack structure CSK discontinuously extend through the gate stack structure 52, and two adjacent doped channel rings 16 are spaced apart from each other by the extension portion 54E of the insulating layer 54. The height H1 of the doped channel collar 16 may be equal to, smaller or larger than the height H2 of the gate layer 38. The height H1 is the width of the channel, and the height H2 is the width of the gate layer 38. When the gate width is greater than the channel width (i.e., the height H2 is greater than the height H1), the gate control capability is better, the subthreshold swing is smaller, and the cell distribution is tighter. When the width of the gate is smaller than the width of the channel (i.e., the height H2 is smaller than the height H1), the on-current increases and the operation (read/write) speed increases.

Referring to FIGS. 1C and 1D, in some embodiments of the disclosure, the doped channel rings 16 have dopant therein. The dopant concentration of the doped channel rings 16 may be 1×10¹⁸ atom/cm³ to 5×10¹⁹ atom/cm³. The conductivity type of the dopant in the doped channel rings 16 is the same as the conductivity type of the dopant in the source pillar 32a and the drain pillar 32b. The dopant concentration of the doped channel rings 16 is smaller than the dopant concentration of the source pillar 32a and the drain pillar 32b. For example, the dopant concentration of the doped channel rings 16 is 1/50 to 1/10 of the dopant concentration of the source pillar 32a and the drain pillar 32b.

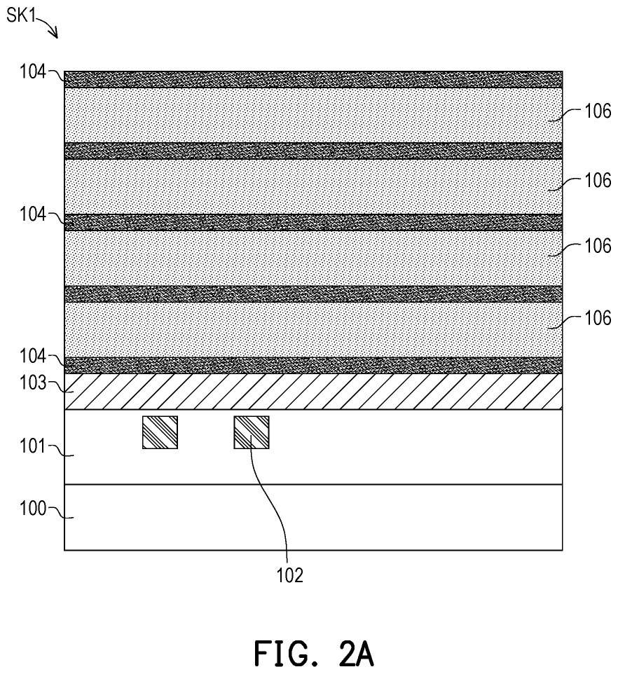

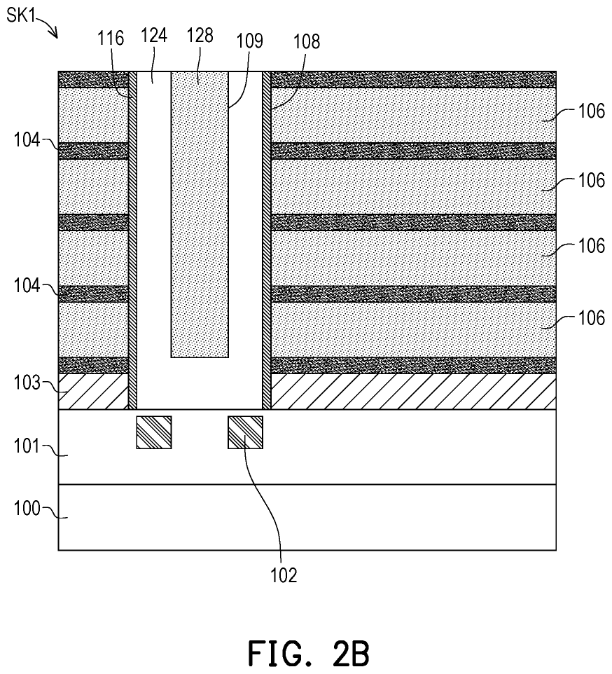

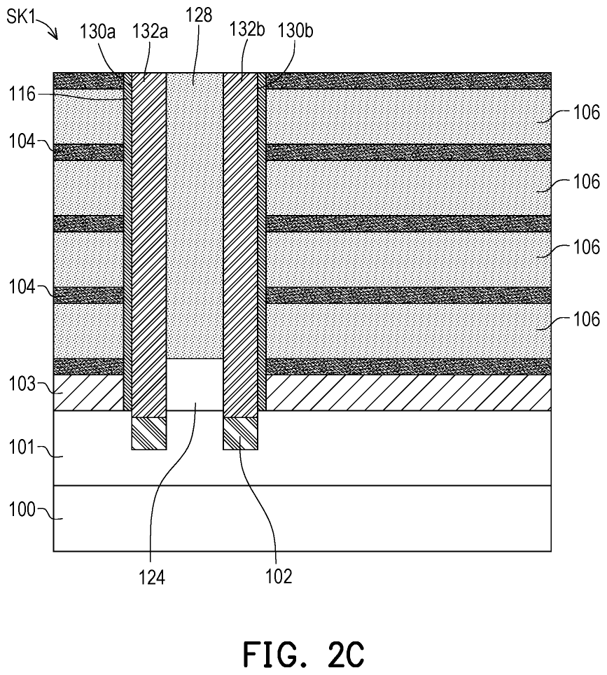

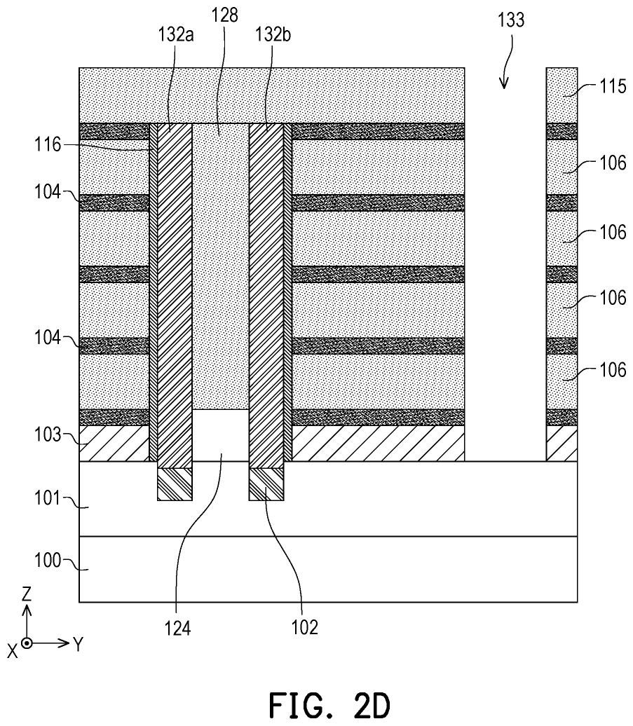

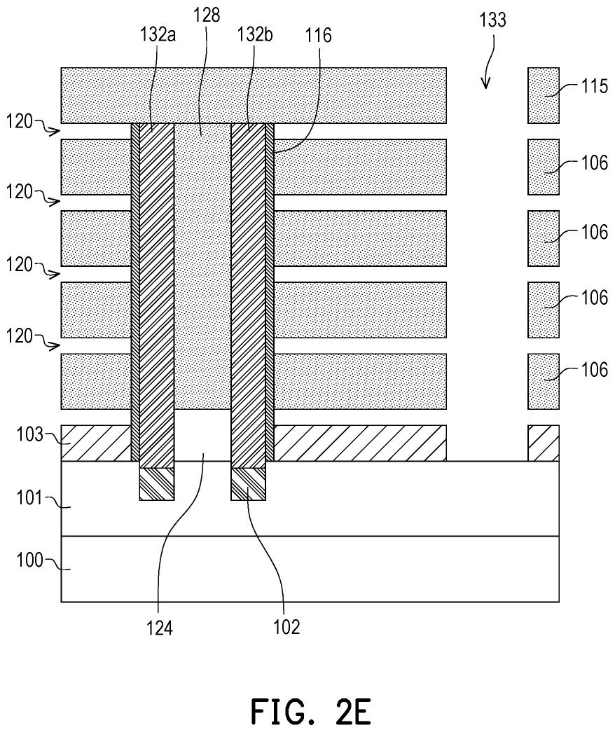

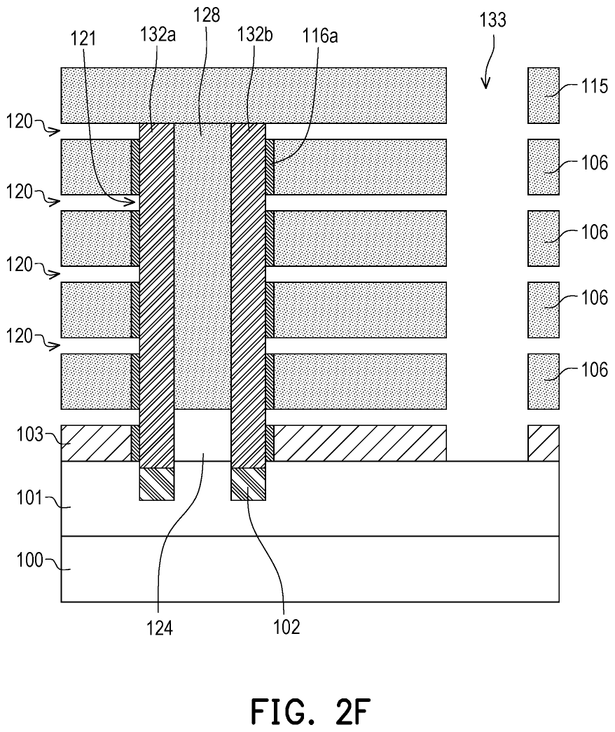

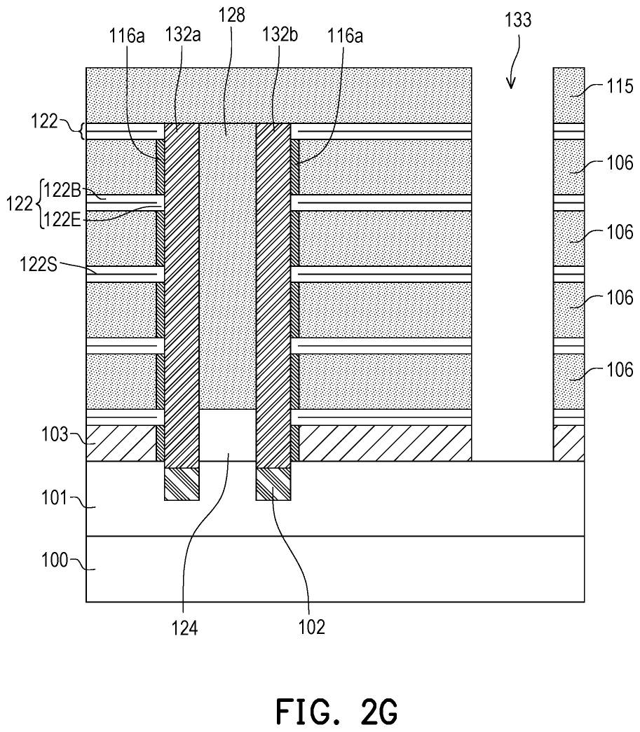

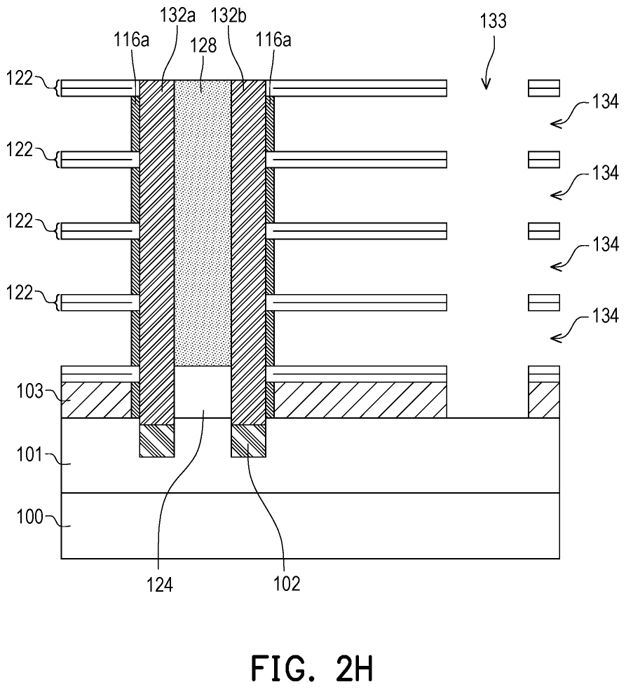

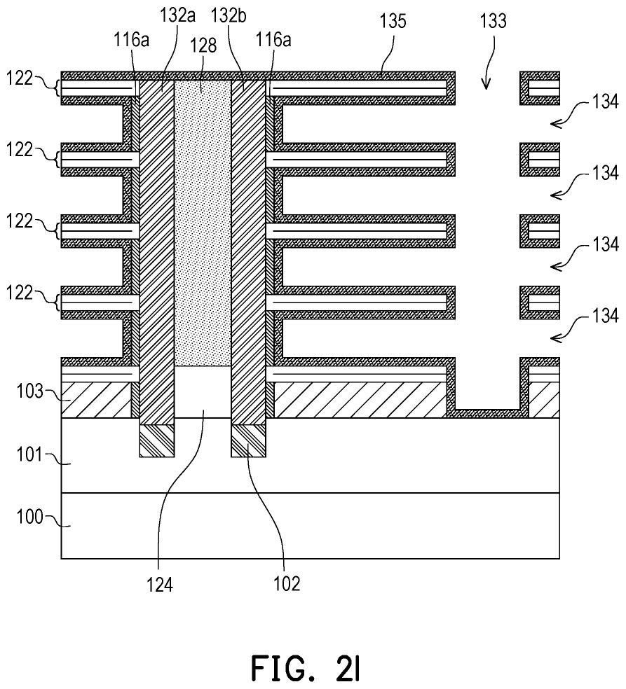

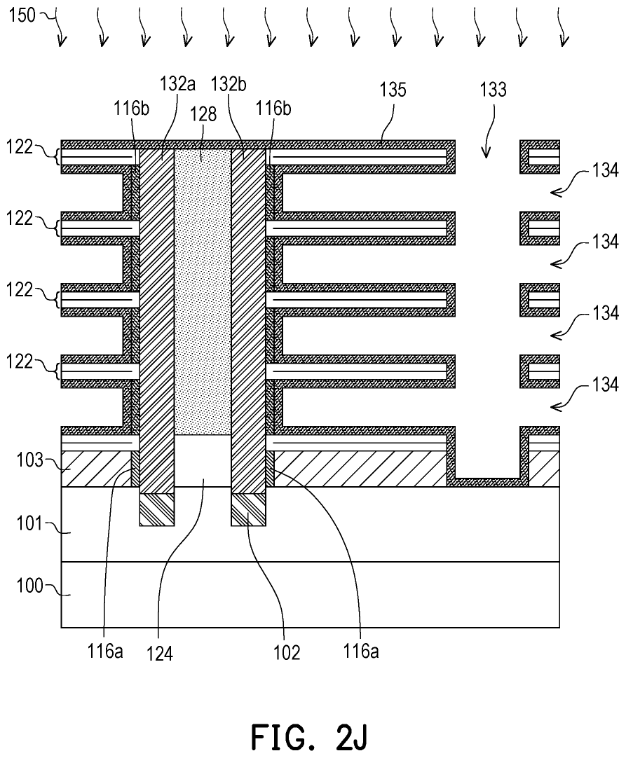

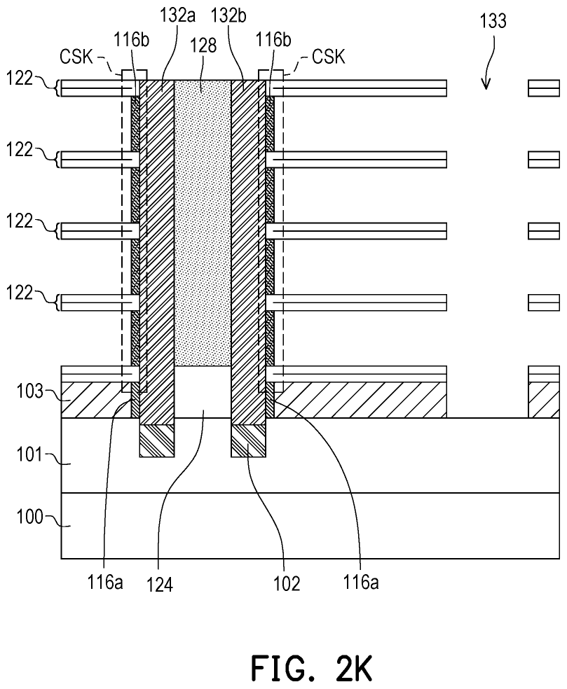

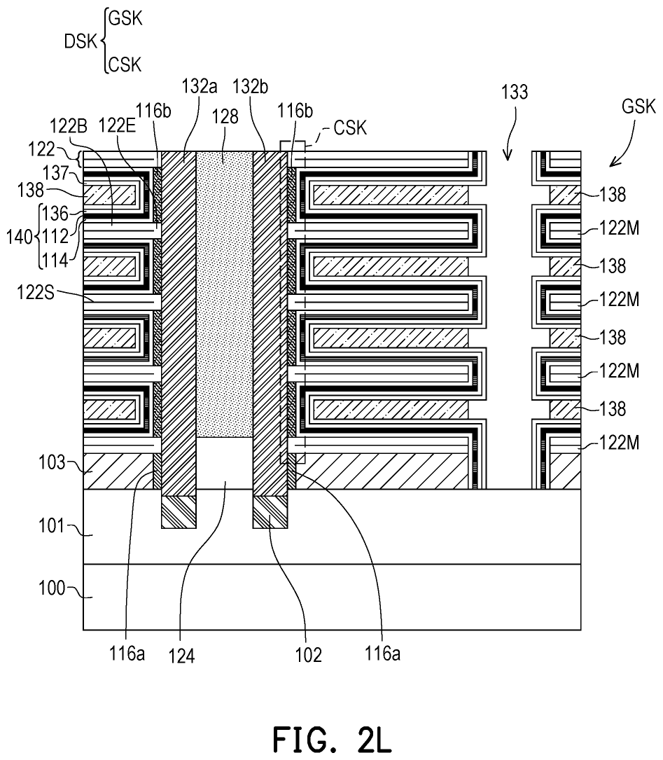

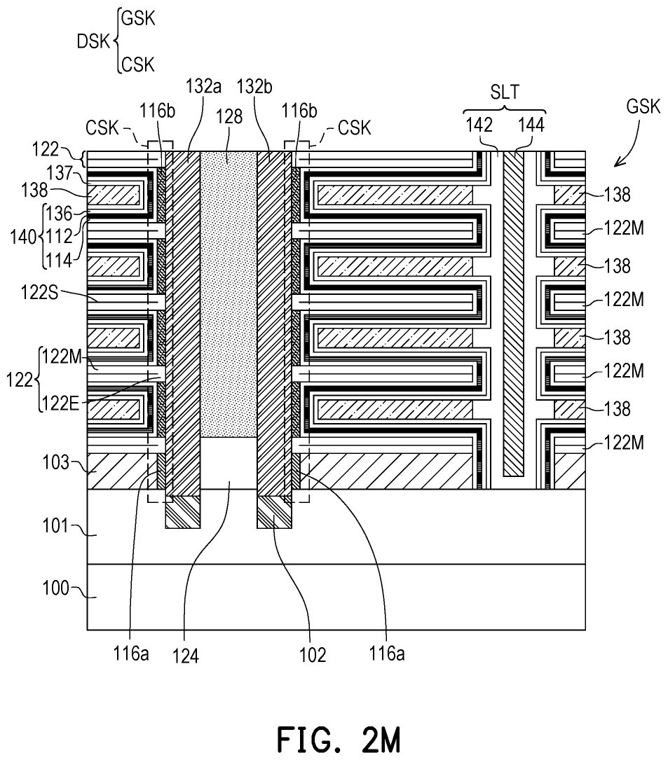

FIG. 2A to FIG. 2M are schematic cross-sectional views of a manufacturing process of a three dimensional AND flash memory semiconductor device according to an embodiment of the disclosure. The semiconductor may be a flash memory device.

Referring to FIG. 2A, a dielectric substrate 100 is provided. The dielectric substrate 100 is, for example, a dielectric layer (e.g., a silicon oxide layer) of a metal interconnect structure formed on a silicon substrate. The dielectric substrate 100 includes an array region (not shown) and a staircase region (not shown). A stack structure SK1 is formed on the dielectric substrate 100 in the array region and the staircase region. The stack structure SK1 may also be referred to as an intermediate stack structure SK1. In this embodiment, the stack structure SK1 is composed of interlayers 104 and interlayers 106 that are alternately stacked alternately stacked on the dielectric substrate 100 in order. In other embodiments, the stack structure SK1 may be composed of interlayers 106 and interlayers 104 that are alternately stacked on the dielectric substrate 100 in order. In addition, in this embodiment, the uppermost layer of the stack structure SK1 is the interlayer 104. In this embodiment, the stack structure SK1 has five interlayers 104 and four interlayers 106, but the disclosure is not limited thereto. In other embodiments, more interlayers 104 and more interlayers 106 may be formed according to the actual requirements. The interlayers 104 are semiconductor materials, for example. The interlayers 106 are silicon nitride, for example. The interlayers 104 and 106 may serve as sacrificial layers which may be partially or entirely removed in the subsequent process. In some embodiments, the interlayers 104 may also be referred to as first interlayers 104, and the interlayer 106 may also be referred to as second interlayers 106.

In some embodiments, before the stack structure SK1 is formed, an insulating layer 101, a stop layer 102 and a conductive layer 103. The insulating layer 101 is, for example, silicon oxide. The stop layer 102 is formed in the insulating layer 101. The stop layer 102 is, for example, a conductive pattern such as a polysilicon pattern. The conductive layer 103 is a ground layer composed of polysilicon. The conductive layer 103 may be also referred to as dummy gates which are used to close the pathway of the leakage current. The stack structure SK1 is patterned to form a staircase structure (not shown) in the staircase region (not shown).

Next, referring to FIG. 2B, a plurality of openings 108 are formed in the stack structure SK1 in the array region. In this embodiment, the opening 108 extends through the conductive layer 103. In this embodiment, from a top view, the opening 108 has a circular profile (not shown), but the disclosure is not limited thereto. In other embodiments, the opening 108 may have other profile such as a polygonal profile (not shown).

Referring to FIG. 2B, a channel pillar 116 is formed in the opening 108. A material of the channel pillar 116 may be semiconductor such as undoped polysilicon. The method of forming the channel pillar 116 includes, for example, forming a channel material on the stack structure SK1 and in the opening 108. The channel material may be formed by using chemical vapor deposition. Then, an etch-back process is performed to partially remove the channel material to form the channel pillar 116. The channel pillar 116 cover the sidewall of the opening 108 and expose the bottom of the opening 108. The channel pillar 116 may extend through the stack structure SK1 and extend into the insulating layer 101 (not shown). The channel pillar 116 may be continuous in its extending direction (e.g., in a direction perpendicular to the dielectric substrate 100). In other words, the channel pillar 116 is integral in its extending direction and is not divided into multiple disconnected parts. In a top view, the channel pillar 116 has, for example, a ring shape (not shown). In some embodiments, the channel pillar 116 may have a circular profile (not shown) in a top view, but the disclosure is not limited thereto. In other embodiments, the channel pillar 116 may also have other profile such as a polygonal profile in a top view (not shown).

Referring to FIG. 2B, an insulating filling material is formed on the stack structure SK1 and filled in the opening 108. The insulating filling material is, for example, low temperature silicon oxide. The insulating filling material filled in the opening 108 forms the insulating filling layer 124 and a circular void is left in the center of the insulating filling layer 124. Then, an anisotropic etching process is performed to expand the circular void to form a hole 109.

Referring to FIG. 2B, an insulating material layer is formed on the insulating filling layer 124 and in the holes 109. Then, an anisotropic etching process is performed to remove part of the insulating material layer to form an insulating pillar 128 in the hole 109. The material of the insulating pillar 128 is different from that of the insulating fill layer 124. The material of insulating pillar 128 is silicon nitride, for example.

Referring to FIG. 2C, a patterning process (e.g., photolithography and etching processes) is performed to form holes 130a and 130b in the insulating filling layer 124. In the etching process, the stop layer 102 may serve as an etching stop layer. Therefore, the formed holes 130a and 130b extend through the stack structure SK1 to expose the stop layer 102. The profiles of the hole patterns defined in the patterning process may be tangent to the profile of the insulating pillar 128. The profiles of the hole patterns defined in the patterning process may also exceed the profile of the insulating pillar 128 (not shown). Since the etching rate of the insulating pillar 128 is lower than the etching rate of the insulating filling layer 124, the insulating pillar 128 is hardly damaged by etching and remains. In addition, in some embodiments, the profile of the hole defined in the patterning process exceed the profile of the opening 108 (not shown).

Referring to FIG. 2C, conductive pillars (or referred to as electrode pillars) 132a and 132b are formed in the holes 130a and 130b. The conductive pillars 132a and 132b may serve as source and drain pillars, respectively, and are electrically connected to the channel pillar 116. The method of forming the conductive pillars 132a and 132b includes forming a conductive material on the interlayer 104 and filled in the holes 130a and 130b, and performing an etch-back process. A material of the conductive pillars 132a and 132b include doped polysilicon.

Referring to FIG. 2D, next, a capping insulating layer 115 is formed over the interlayer 104, the channel pillar 116, the conductive pillars 132a and 132b, the insulating filling layer 124, and the insulating pillar 128. The capping insulating layer 115 is silicon oxide, for example. A patterning process (e.g., photolithography and etching processes) is performed on the capping insulating layer 115 and the stack structure SK1 to form a plurality of slit trenches 133. During the etching process, the insulating layer 101 may be used as the etch stop layer, so that the insulating layer 101 is exposed by the slit trench 133. The slit trench 133 extends along the X direction so that the stack structures SK2 and SK1 in the array region and the staircase region are divided into a plurality of blocks (not shown).

Next, referring to FIG. 2E, an etching process (e.g., a wet etching process) is performed to partially remove the interlayers 104. The etching solution (e.g., hot phosphoric acid) used in the etching process is injected into the slit trench 133, and portions of the interlayers 104 which are in contact with the etching solution are removed. By using a time mode control, most of the interlayers 104 may be removed to form a plurality of horizontal openings 120. The etchant used in the etching process is, for example, an alkaline etchant, such as an amine hydroxide solution, a TMAH solution, or a potassium hydroxide solution. The alkaline etching solution has a relatively high etching selectivity for silicon oxide and silicon nitride.

Referring to FIG. 2F, after that, a dicing process is performed on the channel pillar 116. In some embodiments, the dicing process includes the following steps. First, an etching process is performed to remove the channel pillar 116 exposed by the horizontal openings 120 to form a plurality of ring spaces 121. The channel pillar 116 is cut into a plurality of channel rings 116a separated by the plurality of ring spaces 121. The plurality of ring spaces 121 expose the sidewalls of the conductive pillars 132a and 132b. The etchant used in the etching process is, for example, SC1 solution, which has a lower etching rate to control the etching process more precisely.

Referring to FIG. 2G, a plurality of insulating layers 122 are refilled in the plurality of horizontal openings 120 and the plurality of ring spaces 121. The method of forming the plurality of insulating layers 122 includes the following steps. An insulating material is refilled in the slit trench 133, the plurality of horizontal openings 120, and the plurality of ring spaces 121. After that, an etching process is performed to remove the insulating material in the slit trench 133 to expose the sidewalls of the interlayers 106, and left the plurality of insulating layers 122 in the plurality of horizontal openings 120 and the plurality of ring spaces 121. Each insulating layer 122 may include a body portion 122B and an extension portion 122E connected to each other. The plurality of body portions 122B are located in the horizontal opening 120, and are stacked alternately with the plurality of interlayers 106. The plurality of extension portions 122E are located in the plurality of ring spaces 121 are alternately stacked with the plurality of channel rings 116a. In some embodiments, since the insulating layer 122 is formed in the plurality of horizontal openings 120 and the plurality of ring spaces 121 by way of refilling, the insulating layer 122 has an interface, a seam or a void 122S therein.

Referring to FIG. 2H to FIG. 2J, before performing a replacement process to replace the interlayers 106 with a plurality of gate layers 138 and a plurality of charge storage structures 140, a doping process for the channel ring 116 is performed to form a plurality of doped channel rings 116b.

First, referring to FIG. 2H, the doping process for the channel ring 116a includes the following steps. First, an etching process, such as a wet etching process, is performed to remove the plurality of interlayers 106. The etchant used in the etching process (e.g., hot phosphoric acid) is injected into the slit trench 133, and portions of the interlayers 106 which are in contact with the etching solution are removed. The etching process is performed, and most of the interlayer 106 is removed to form a plurality of horizontal openings 134 by using a time mode control. The sidewalls of the channel rings 116a above the conductive layer 103 are exposed by the plurality of horizontal openings 134. The lowermost channel ring 116a is still surrounded by the conductive layer 103.

Referring to FIG. 2I, a doped layer 135 is formed in the slit trench 133 and the plurality of horizontal openings 134. In some embodiments, the conductivity type of the dopant in the doped layer 135 is the same as the conductivity type of the dopant in the conductive pillars 132a and 132b. Both the doped layer 135 and the conductive pillars 132a and 132b have N-type dopants, or both the doped layer 135 and the conductive pillars 132a and 132b have P-type dopants. In other some embodiments, the conductivity type of the dopant in the doped layer 135 is different from the conductivity type of the dopant in the conductive pillars 132a and 132b. The ratio of the thickness of the channel ring 116a to the thickness of the doped layer 135 is, for example, 3:1 to 10:1. The material of the doped layer 135 is, for example, doped polysilicon. The formation method of the doped layer 135 is, for example, a chemical vapor deposition. The doped layer 135 is in contact with the plurality of channel rings 116a exposed to the plurality of horizontal openings 134. The lowermost channel ring 116a is surrounded by the conductive layer 103 and therefore does not contact the undoped layer 135.

Referring to FIG. 2J, a thermal process 150 is performed, so that the dopant in the doped layer 135 is diffused into the plurality of channel rings 116a to form a plurality of doped channel rings 116b. The thermal process 150 is, for example, a rapid thermal annealing (RTA) process or a high temperature furnace process. The temperature of the rapid thermal tempering process is, for example, 850 degrees Celsius to 1050 degrees Celsius, and the time for the RTA process is, for example, 30 seconds to 90 seconds. The temperature of the high temperature furnace process is, for example, 650 degrees Celsius to 750 degrees Celsius, and the time for the high temperature furnace process is, for example, 2 hours to 6 hours.

Referring to FIG. 2H, the conductivity type of the dopant in the plurality of doped channel rings 116b is the same as the conductivity type of the dopant in the conductive pillars 132a and 132b because of the doped layer 135 is the same as the conductivity type of the dopant in the conductive pillars 132a and 132b. In some embodiments, both the doped layer 135 and the conductive pillars 132a and 132b have N-type dopants. In other some embodiments, both the doped layer 135 and the conductive pillars 132a and 132b have P-type dopants. The dopant concentration of the plurality of doped channel rings 116b is smaller than the dopant concentration of the conductive pillars 132a and 132b. For example, the dopant concentration of the plurality of doped channel rings 116b is 1/50 to 1/10 of the dopant concentration of the conductive pillars 132a and 132b. The dopant concentrations of the plurality of doped channel rings 116b may be modulated and controlled by the thickness and the dopant concentration of the doped layer 135 and the thickness of the channel ring 116a.

For example, the doping concentration of the formed channel ring 116a may be reduced by reducing the thickness or concentration of the doped layer 135, or increasing the thickness of the channel ring 116a. In some embodiments, the channel ring 116a has a thickness of 200 angstroms, and the doped layer has a thickness of 25 angstroms and a dopant concentration of 3×10²⁰ atom/cm³. After the thermal process 150 is performed, the plurality of doped channel rings 116b are formed, and the dopant concentration of the doped channel rings 116b may reach 6×10¹⁸ atom/cm³. In other some embodiments, t the channel ring 116a has a thickness of 200 angstroms, and the doped layer has a thickness of 35 angstroms and a dopant concentration of 3×10²⁰ atom/cm³. After the thermal process 150 is performed, the plurality of doped channel rings 116b are formed, and the dopant concentration of the doped channel rings 116b may reach 1×10¹⁹ atom/cm³. In still other some embodiments, the channel ring 116a has a thickness of 100 angstroms, and the doped layer has a thickness of 35 angstroms and a dopant concentration of 3×10²⁰ atom/cm³. After the thermal process 150 is performed, the plurality of doped channel rings 116b are formed, and the dopant concentration of the doped channel rings 116b may reach 2×10¹⁹ atom/cm³.

Referring to FIG. 2K, an etching process is performed to remove the doped layer 135, thereby exposing the sidewalls of the doped channel rings 116b and the surfaces of the insulating layers 122. The etching process is, for example, a dry etch process, a wet etching process, or a combination thereof. The plurality of doped channel rings 116b and the plurality of extension portions 122E of the plurality of insulating layers 122 are alternately stacked to form a doped channel stack structure CSK.

Referring to FIG. 2L, next, a replacement process is performed. A plurality of tunneling layer 114, a plurality of charge storage layer 112, a plurality of block layer 136 and a plurality of gate layer 138 are formed in the plurality of horizontal openings 134. The tunneling layers 114 are silicon oxide, for example. The charge storage layers 112 are silicon nitride, for example. The block layers 136 are include, for example, silicon oxide, a material with high dielectric constant greater than or equal to 7, or a combination thereof. The material with high dielectric constant greater than or equal to 7 may be aluminum oxide (Al₂O₃), hafnium oxide (HfO₂), lanthanum oxide (La₂O₅), a transition metal oxide, a lanthanide oxide, or combinations thereof. The gate layer 138 is, for example, tungsten. In some embodiments, barrier layers 137 are also formed before the plurality of gate layers 138 are formed. The material of the barrier layers 137 are, for example, titanium (Ti), titanium nitride (TiN), tantalum (Ta), tantalum nitride (TaN) or a combination thereof.

The formation method of the tunneling layers 114, the charge storage layers 112, the block layers 136, the barrier layers 137, and the gate layers 138 includes, for example, the following steps. A tunnel material, a storage material, a barrier material, a barrier material, and a conductive material are sequentially formed in the slit trench 133 and the horizontal openings 134. An etch-back process is then performed to remove the tunneling material, the storage material, the barrier material, the barrier material and the conductor material in the plurality of slit trenches 133 to form the tunneling layers 114, the charge storage layers 112, the block layers 136, the barrier layers 137, and the gate layers 138 in the plurality of horizontal openings 134. The tunneling layer 114, the charge storage layer 112, and the block layer 136 are collectively referred to as a charge storage structure (or a dielectric structure) 140. So far, the gate stack structure GSK is formed. The gate stack structure GSK is disposed over the dielectric substrate 100 and includes the plurality of gate layer 138 and the plurality of body portions 122M of the plurality of insulating layer 122 which are stacked alternately with each other. The gate stack structure GSK and the doped channel stack structure CSK together form a double stack structure DSK.

Referring to FIG. 2M, a slit structure SLT is formed in the slit trench 133. The method for forming the slit structure SLT includes forming the insulating liner material and the conductive material over the gate stack structure GSK and filling in the slit trench 133. The insulating liner material is, for example, silicon oxide. The conductive material is, for example, polysilicon. Then, the excess insulating liner material and the excess conductive material over the gate stack structure GSK are removed through an etching process or a planarization process to form a liner layer 142 and a conductive layer 144. The liner layer 142 and the conductive layer 144 are collectively referred to as the slit structure SLT. In other embodiments, the slit structure SLT may also be completely filled with the insulating material without any conductive layer. In still other embodiments, the slit structure SLT may also be the liner layer 142, and the liner layer 142 has an air gap therein without any conductive layer.

After that, a plurality of contacts (not shown) are formed in the staircase region. The contact lands on the end of the gate layer 138 in the staircase region, and is electrically connected to the gate layer 138 respectively.

The manufacturing method of the memory device of the embodiment of the disclosure may be applied to a three dimensional AND flash memory device or a three dimensional NOR flash memory device, and may be integrated with the existing process, in which a channel pillar penetrating through the gate stack structure is cut into a plurality of channel rings and is doped.

In the embodiments of the disclosure, the channel rings are physically separated from each other with the insulating layers. This helps the gate layer to control the channel region, so as to reduce the leakage current between the memory cells, increase the device window, and improve the current ratio of turn-on and turn-off (Ion/Ioff). Furthermore, since the channel rings are doped, the threshold voltage of the device may be modulated by changing the dopant concentration of the channel region to improve the current of turn-on and avoid to punch through.

What is claimed is:

1. A memory device, comprising:
a gate stack structure located on a substrate, wherein the gate stack structure comprises a plurality of gate layers and a plurality of insulating layers stacked alternately with each other;
a doped channel stack structure extending through the gate stack structure, wherein the doped channel stack structure comprises a plurality of doped channel rings spaced apart from each other;
a source pillar and a drain pillar extending through the doped channel stack structure, wherein the source pillar and the drain pillar are respectively electrically connected to the plurality of doped channel rings; and
a plurality of dielectric structures located between the plurality of gate layers and the plurality of doped channel rings.

2. The memory device of claim 1, wherein a conductivity type of dopants in the plurality of doped channel rings is the same as a conductivity type of the dopants in the source pillar and the drain pillar.

3. The memory device of claim 1, wherein a dopant concentration of the plurality of doped channel rings is 1/50 to 1/10 of dopant concentrations of the source pillar and the drain pillar.

4. The memory device of claim 1, wherein the plurality of insulating layers comprises:
a plurality of body portions, stacked alternately with the plurality of gate layers; and
a plurality of extension portions, connected to the plurality of body portions, and stacked alternately with the plurality of doped channel rings to form the doped channel stack structure.

5. The memory device of claim 1, wherein at least one of the plurality of insulating layers has an interface, a seam or a void.

6. A method of fabricating a memory device, comprising:
forming an intermediate stack structure on a substrate, wherein the intermediate stack structure comprises a plurality of first interlayers and a plurality of second interlayers stacked alternately with each other;
forming opening in the intermediate stack structure;
forming a channel pillar on a sidewall of the opening;
forming a source pillar and a drain pillar within the channel pillar, wherein the source pillar and the drain pillar are electrically connected to the channel pillar;
removing the plurality of first interlayers to form a plurality of first horizontal openings;
removing a portion of the channel pillar exposed by the plurality of first horizontal openings to form a plurality of ring spaces and etching the channel pillar to form a plurality of channel rings, wherein the plurality of channel rings are separated from each other by the plurality of ring spaces;
filling a plurality of insulating layers into the plurality of first horizontal openings and the plurality of ring spaces;
removing the plurality of second interlayers to form a plurality of second horizontal openings;
performing a doping process on the plurality of channel rings to form a plurality of doped channel rings, wherein the plurality of doped channel rings and the plurality of insulating layers filled in the plurality of ring spaces are alternately stacked to form a doped channel stack structure;
filling a plurality of gate layers in the plurality of second horizontal openings, wherein the plurality of gate layers and the plurality of insulating layers filled in the plurality of first horizontal openings alternate with each other to form a gate stack structure; and
forming a plurality of dielectric structures between the plurality of gate layers and the plurality of doped channel rings.

7. The method of claim 6, wherein performing the doping process comprises:
filling a plurality of doped layers in the plurality of second horizontal openings;
performing a thermal process to diffuse dopants in the doped layer to the plurality of channel rings to form the plurality of doped channel rings; and
removing the doped layer.

8. The method of claim 7, wherein a conductivity type of the dopants in the doped layer is the same as a conductivity type of dopants in the source pillar and the drain pillar.

9. The method of claim 7, wherein the thermal process comprises a rapid thermal annealing process or a furnace process.

10. The method of claim 7, wherein filling the plurality of insulating layers comprises forming an interface, a seam or a void in at least one of the plurality of insulating layers.

11. A semiconductor device, comprising:
a stack structure, located on the substrate, wherein the stack structure comprises a plurality of conductive layers;
a vertical pillar extending through the stack structure, wherein the vertical pillar includes a plurality of channel rings spaced apart from each other, the plurality of channel rings having a first doping concentration; and
two electrode pillars extending through the stack structure, wherein the two electrode pillars have a second doping concentration and are respectively electrically connected to the plurality of channel rings, and the first doping concentration is smaller than the second doping concentration.

12. The semiconductor device of claim 11, wherein the conductivity type of the dopant of the plurality of channel rings is the same as the conductivity type of the dopant of the two electrode pillars.

13. The semiconductor element of claim 11, wherein the first doping concentration is 1/50 to 1/10 of the second doping concentration.

14. The semiconductor element of claim 11, wherein the stack structure comprises a plurality of insulating layers and the plurality of conductive layers are alternately stacked with each other, and the plurality of insulating layers extend to gaps between the plurality of channel rings.

15. The semiconductor device of claim 11, further comprising a plurality of dielectric structures located on sidewalls of the plurality of channel rings.
